(19) United States
(12) Patent Application Publication
(10) Pub. No.: US 2007/0163489 A1
(43) Pub. Date: Jul. 19, 2007

(54) Method of forming a layer having a single crystalline structure

(76) Inventors: Yong-Hoon Son, Yongin-si (KR); Jong-Wook Lee, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 11/652,619

(22) Filed: Jan. 12, 2007

(30) Foreign Application Priority Data
Jan. 16, 2006 (KR) 2006-4335

(51) Int. Cl. C30B 25/00; C30B 23/00; C30B 28/12

(52) U.S. Cl. 117/92; 117/89; 117/108

(57) ABSTRACT

A method of forming a layer, including forming an insulation layer having an opening on a single crystalline substrate, the opening partially exposing an upper face of the substrate, forming a first seed layer in the opening, converting an upper portion of the first seed layer to a first amorphous layer, converting the first amorphous layer to a second seed layer, forming a second amorphous layer on the second seed layer, and converting the second amorphous layer to a single crystalline layer.

### BACKGROUND OF THE INVENTION

1. Field of the Invention

Embodiments of the present invention relate to a method of forming a layer having a single crystalline structure. More particularly, embodiments of the present invention relate to a method of forming a layer having a single crystalline structure that may be used for a channel layer in a stacked structure such as a semiconductor device.

2. Description of the Related Art

Generally, the crystallinity of a material may be classified as a single crystalline structure, a poly-crystalline structure, an amorphous structure, etc., based on the crystal characteristics of the material. The single crystalline material may have only one crystal, the poly-crystalline material may have multiple crystals, e.g., crystals of varying orientations, and the amorphous material may have an irregular, non-crystalline arrangement of atoms.

A single crystalline material, e.g., a single crystalline silicon layer, may be desirable for fabricating a thin layer in an active region of a semiconductor device, e.g., a system-on-chip (SOC) including a thin film transistor (TFT) having a stacked structure. In contrast, a poly-crystalline material, which may have multiple crystal grain boundaries, may be less desirable. In particular, when there are too many grain boundaries, charge carrier mobility may be poor, i.e., mobility control over a carrier such as an electron or a hole may be interrupted.

A single crystalline layer may be formed using a method that includes forming an insulation layer on a single crystalline substrate and pattering the insulation layer so as to form an opening therein that exposes the single crystalline substrate. A selective epitaxial growth (SEG) process may then be performed on the exposed crystalline silicon substrate to form a single crystalline seed layer in the opening, after which an amorphous layer may be formed on the insulation layer pattern and the seed layer. The amorphous layer may then be thermally treated so as to convert the amorphous layer into a single crystalline layer. In particular, the underlying seed layer may impart a crystal structure to the amorphous layer through a phase change of the amorphous layer.

A single crystalline layer formed as just described is illustrated in FIG. 1, which illustrates a scanning electron microscopic (SEM) analysis of a single crystalline layer formed using a conventional method. Referring to FIG. 1, the crystallinity of the seed layer is characterized by a facet morphology, where the single crystalline structure of the seed layer is inclined or oriented at an angle with respect to the crystal structure of the underlying surface, i.e., with respect to the major surface of the underlying substrate. In particular, where an upper surface of the underlying substrate has a {100} crystal orientation, the single crystalline layer grown on the upper surface of the substrate using SEG may have a {111} crystal orientation. In this case, when the crystalline structure of the seed layer has a {111} crystal plane, the facet morphology is inclined by about 54.7° with respect to the crystal plane of the underlying substrate at the bottom face of the opening.

When the crystalline structure of the seed layer has such a facet morphology, the facet morphology may be translated into the amorphous layer overlying the seed layer during the phase change of the second amorphous layer. That is, the facet morphology may propagate into the single crystalline layer obtained as a result of the phase change of the amorphous layer. This facet morphology in the single crystalline layer may be detrimental to the electrical reliability of a semiconductor device formed thereon. Thus, since the facet morphology may be detrimental to the electrical reliability of the device, the single crystalline silicon layer may not be particularly suitable for a channel layer of a stacked device structure.

### SUMMARY OF THE INVENTION

The present invention is therefore directed to a method of forming a layer having a single crystalline structure, which substantially overcomes one or more of the problems due to the limitations and disadvantages of the related art.

It is therefore a feature of an embodiment of the present invention to provide a method of forming a layer having a single crystalline structure, the method including treating a seed layer so as to remove facet morphology from a portion of the seed layer.

It is therefore another feature of an embodiment of the present invention to provide a method of forming a layer having a single crystalline structure, the method including converting an upper portion of a seed layer to an amorphous layer and recrystallizing the amorphous layer.

It is therefore yet another feature of an embodiment of the present invention to provide a method of forming a layer having a single crystalline structure, the method including converting an upper portion of a seed layer to an amorphous layer, wherein the thickness of the amorphous layer corresponds to a crystal structure of the seed layer.

At least one of the above and other features and advantages of the present invention may be realized by providing a method of forming a layer, including forming an insulation layer having an opening on a single crystalline substrate, the opening partially exposing an upper face of the substrate, forming a first seed layer in the opening, converting an upper portion of the first seed layer to a first amorphous layer, converting the first amorphous layer to a second seed layer, forming a second amorphous layer on the second seed layer, and converting the second amorphous layer to a single crystalline layer

The substrate may be at least one of single crystalline silicon and single crystalline germanium. The insulation layer may include an oxide. Converting the first seed layer into the first amorphous layer may include implanting the first seed layer with ions. The substrate may be at least one of single crystalline silicon and single crystalline germanium, and the ions may include at least one of silicon, germanium, arsenic, phosphorous and boron.

A thickness of the first amorphous layer may be about 1.3 times to about 1.5 times a width of the opening. A thickness of the first amorphous layer may be determined based on an angle of intersection between a crystal plane of the substrate and a crystal plane of the first seed layer. The thickness of the first amorphous layer may also be determined based on a sidewall profile of the opening.

A thickness of the first amorphous layer may correspond to a width of the first seed layer in the opening, and an angle of intersection between a crystal plane of the substrate and a crystal plane of the first seed layer. The thickness of the first amorphous layer may be approximately equal to the tangent of the angle times the width of the first seed layer.

The substrate may have a {100} crystal structure, the first seed layer may have a {111} crystal structure, the angle of intersection between the substrate and the first seed layer may be approximately 54.7°, and the thickness of the first amorphous layer may be approximately equal to 1.4 times the width of the first seed layer.

The first seed layer may be formed using epitaxy. The first seed layer may have a same composition as the single crystalline substrate. The first seed layer may have a facet morphology, and converting the upper portion of the first seed layer to the first amorphous layer may remove the facet morphology from the upper portion of the first seed layer.

The first amorphous layer may be converted to the second seed layer by heating the first amorphous layer with a laser. The second amorphous layer may be converted to the single crystalline layer by heating the second amorphous layer with a laser. A laser emitter for converting the first amorphous layer may be substantially the same as that for converting the second amorphous layer. Converting the first amorphous layer may include heating the first amorphous layer to its melting temperature, and converting the second amorphous layer may include heating the second amorphous layer to its melting temperature.

The substrate may have a {100} crystal structure and the first seed layer may have a {111} crystal structure. A thickness of the first amorphous layer may correspond to a crystal structure of the first seed layer.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a scanning electron microscopic analysis of a single crystalline layer formed using a conventional method;

FIGS. 2A to 2G illustrate cross-sectional views of stages in a method of forming a single crystalline layer according to an exemplary embodiment of the present invention; and

FIG. 3 illustrates a flow chart of a method of forming a single crystalline layer according to an exemplary embodiment of the present invention.

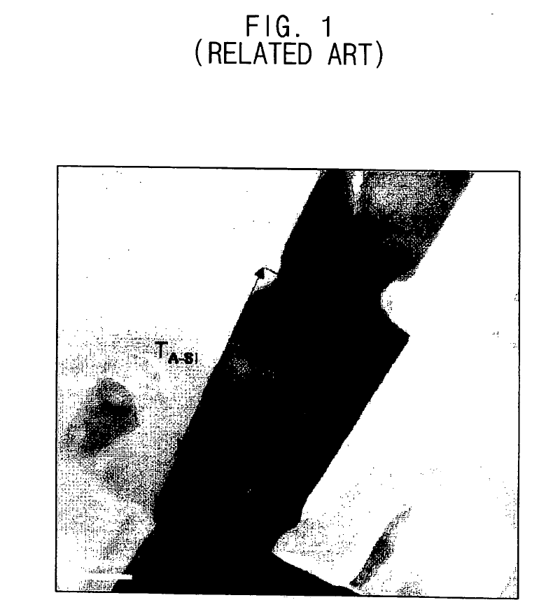

### DETAILED DESCRIPTION OF THE INVENTION

Korean Patent Application No. 2006-4335 filed on Jan. 16, 2006, in the Korean Intellectual Property Office, and entitled: “Method of Forming a Layer Having a Single Crystalline Structure,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present.

It will be understood that when an element or layer is referred to as being “connected to” or “coupled to” another element or layer, it can be directly connected or coupled to the other element or layer or intervening elements or layers may be present. In contrast, when an element is referred to as being “directly on,” “directly connected to” or “directly coupled to” another element or layer, there are no intervening elements or layers present. To the extent used herein, the term “and/or” includes any and all combinations of one or more of the associated listed items.

It will be understood that, although the terms “first,” “second,” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Exemplary embodiments of the present invention are described herein with reference to cross-sectional illustrations that are schematic illustrations of idealized embodiments (and intermediate structures) of the present invention. As such, variations from the shapes of the illustrations as a result of, e.g., manufacturing techniques and/or tolerances, are to be expected. Thus, exemplary embodiments of the present invention should not be construed as limited to the particular shapes of regions illustrated herein, and may include deviations in shapes that result from, e.g., manufacturing. For example, an implanted region illustrated as a rectangle may have rounded or curved features and/or a gradient of implant concentration at its edges, rather than a binary change from an implanted to a non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

In the figures, the dimensions of layers and regions may be exaggerated for clarity of illustration. Like reference numerals refer to like elements throughout.

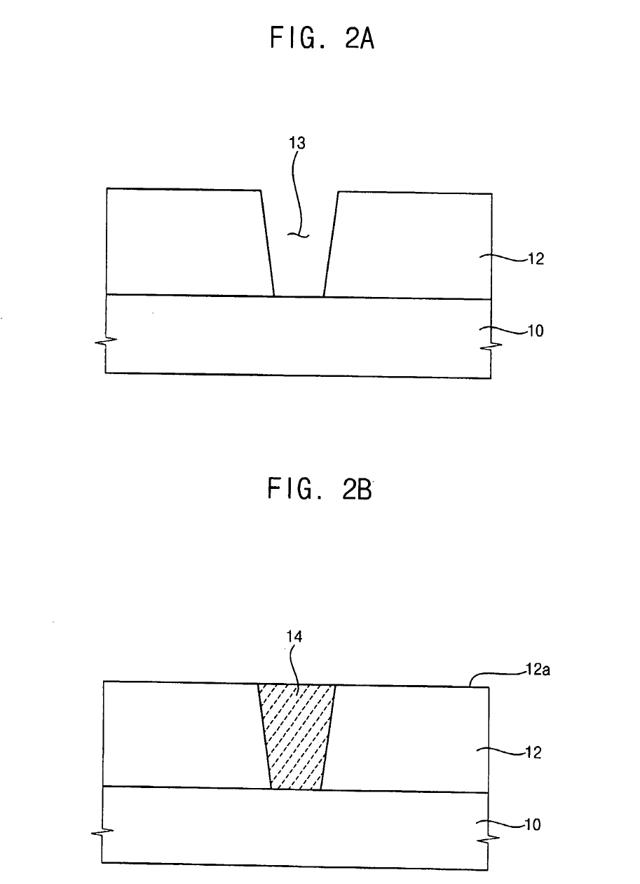

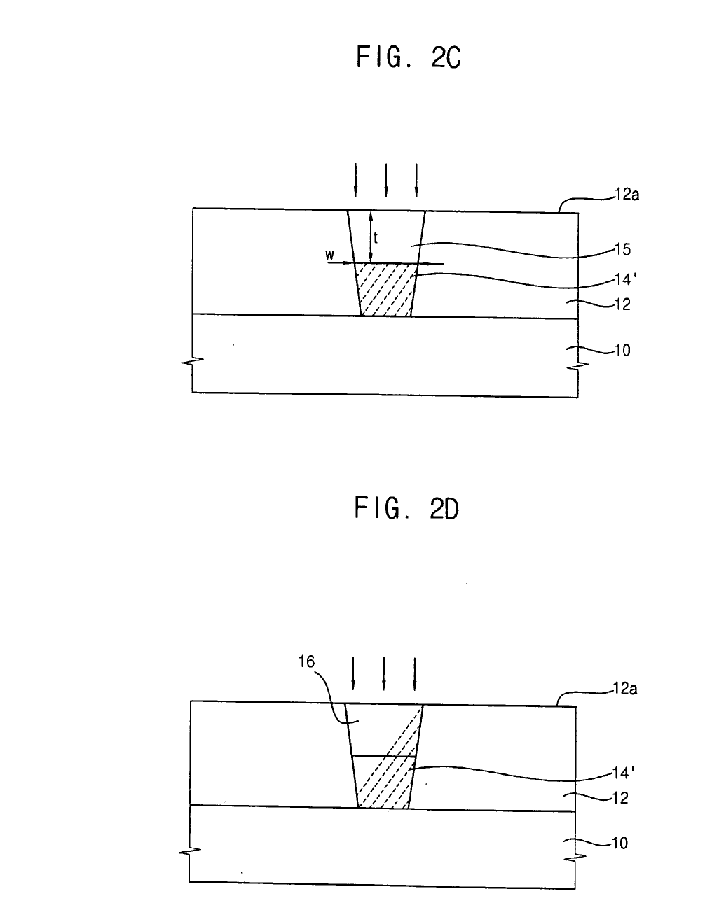

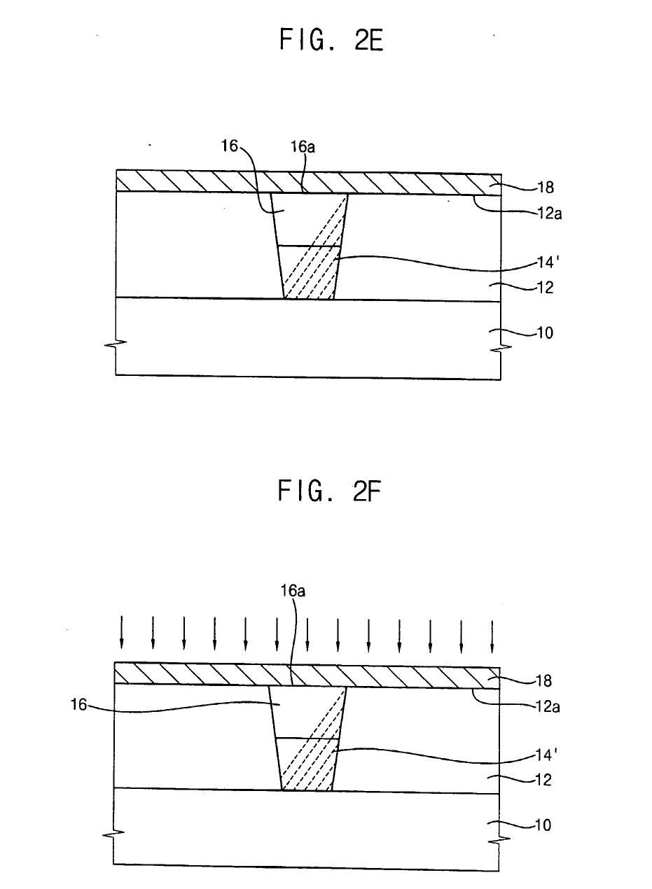

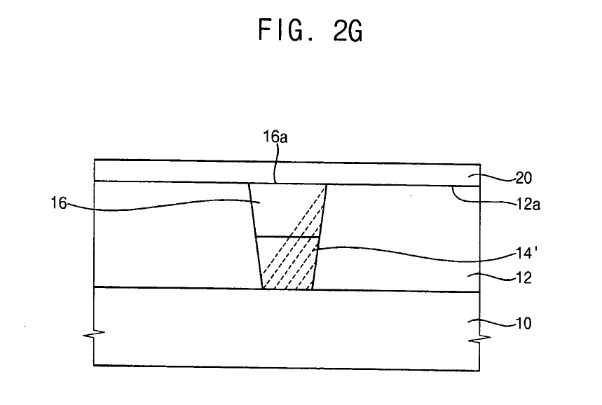

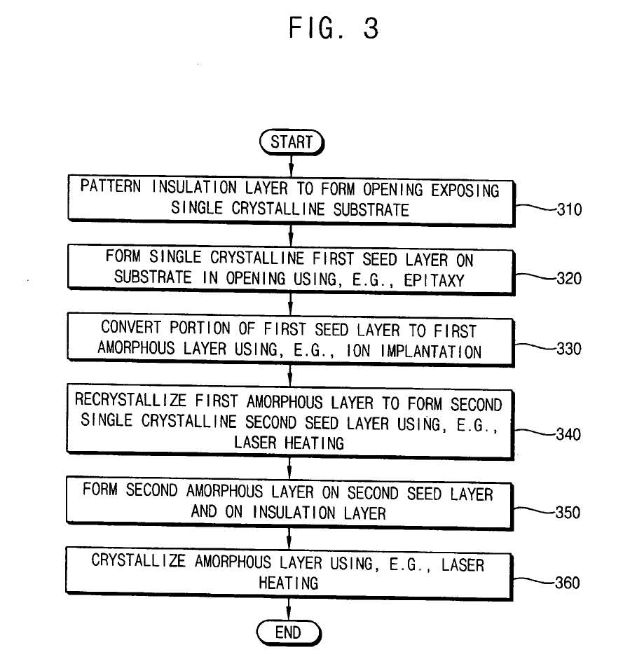

FIGS. 2A to 2G illustrate cross-sectional views of stages in a method of forming a single crystalline layer according to an exemplary embodiment of the present invention, and FIG. 3 illustrates a flow chart of a method of forming a single crystalline layer according to an exemplary embodiment of the present invention. Operations described in FIG. 3 will be indicated parenthetically.

Referring to FIGS. 2A and 3, a substrate 10 having single crystalline structure may be provided. The term “substrate” is to be interpreted broadly, and may include, e.g., a wafer, a stacked or bonded wafer, portions thereof, etc. Additionally, the term may refer to a layer or multiple layers of a multilayered structure, e.g., a particular device layer.

The single crystalline substrate 10 may be used for a semiconductor device structure such as a gate pattern, a metal wiring, a logic device, etc. The single crystalline substrate 10 may be, e.g., a single crystalline silicon substrate, a single crystalline germanium substrate, etc. In another implementation, the single crystalline substrate 10 may correspond to an upper layer of a stack structure. For example, the single crystalline substrate 10 may include a single crystalline silicon layer formed by a SEG process, a single crystalline germanium layer formed by a SEG process, etc, a silicon-on-insulator (SOI) substrate, a germanium-on-insulator (GOI) substrate, etc.

For convenience, the following description may refer to a particular implementation wherein the single crystalline substrate 10 is a single crystalline silicon substrate. However, embodiments of the present invention are not limited thereto.

An insulation layer may be formed on the single crystalline substrate 10 and patterned to yield an insulation layer pattern 12 having an opening 13 (operation 310). The single crystalline substrate 10 may be partially exposed through the opening 13.

In detail, in an implementation, an insulation layer (not shown) may be formed on the single crystalline substrate 10. The insulation layer may include, e.g., an oxide material. The insulation layer may be etched using a photoresist pattern (not shown) as an etching mask to form the insulation layer pattern 12 on the single crystalline substrate 10, with the opening 13 exposing the single crystalline substrate 10. It will be appreciated that more than one opening 13 may be provided, e.g., two or more openings 13 may be provided so as to expose two or more portions of the single crystalline substrate 10 through the openings 13.

Referring to FIG. 2B, after the insulation layer pattern 12 having the opening 13 is formed, a first seed layer 14 may be formed in the opening 13 (operation 320). The first seed layer 14 may have a single crystalline structure.

In an implementation, the first seed layer 14 may be formed using, e.g., an epitaxial growth process such as SEG. The epitaxy may be carried out on the portion of the single crystalline substrate 10 exposed through the opening 13 so that the first seed layer 14 having a single crystalline structure grows epitaxially from the exposed upper face of the single crystalline substrate 10. The opening 13 may be filled with the first seed layer 14. If the above-described process yields a first seed layer 14 having an upper face that is higher than that of the insulation layer pattern 12 surrounding the opening 13, a portion of the first seed layer 14 that projects above an upper surface 12a of the insulation layer pattern 12 may be removed, e.g., using a chemical mechanical polishing (CMP) process.

The first seed layer 14 may have a composition that is substantially the same as the single crystalline substrate 10. That is, where the single crystalline substrate 10 is a single crystalline silicon substrate, the first seed layer 14 may likewise be single crystalline silicon. Further, where the single crystalline substrate 10 is a single crystalline germanium substrate, the first seed layer 14 may be single crystalline germanium.

Referring to FIG. 2C, an upper portion of the single crystalline first seed layer 14 may be converted to a first amorphous layer 15 (operation 330), such that the first amorphous layer 15 does not exhibit a facet morphology of the first seed layer 14. That is, since the structure of the first amorphous layer 15 is not crystallized, the facet morphology of the first seed layer 14 may be removed by the phase change. Thus, according to this embodiment of the present invention, the effects of the facet morphology of the first seed layer 14 on subsequently-formed layers may be reduced or eliminated, as described in greater detail below.

According to an embodiment of the present invention, the upper portion of the first seed layer 14 may be converted into the first amorphous layer 15 using an ion implantation. That is, the upper portion of the first seed layer 14 may be implanted with ions in order to convert the upper portion of the first seed layer 14 to the first amorphous layer 15. The depth of the ion implantation may be controlled so as to form the first amorphous layer 15 to a predetermined thickness -t-, as described in greater detail below.

Ions implanted in the first seed layer 14 may include one or more of, e.g., silicon, germanium, arsenic, phosphorous, boron, etc. The first seed layer 14 may be implanted with ions of the same material as the first seed layer 14, e.g., silicon ions may be implanted in a single crystalline silicon seed layer 14. Alternatively, the first seed layer 14 may be implanted with different ions, i.e., doped with impurities.

In a subsequent process, which is described in greater detail below, a second amorphous layer may be formed on the substrate 10 and crystallized. In order to provide a seed layer for the crystallization, the first amorphous layer 15 may be recrystallized. That is, were a single crystalline layer to be formed on an amorphous layer, the amorphous layer might not sufficiently function as a seed during the phase change. Therefore, according to this exemplary embodiment of the present invention, the first amorphous layer 15 may be converted into a second seed layer 16 having a single crystalline structure.

Thus, referring to FIG. 2D, the first amorphous layer 15 may be recrystallized (operation 340). In an implementation, a first laser beam may be irradiated onto the first amorphous layer 15, so as to convert the first amorphous layer 15 into the second seed layer 16. In particular, the first laser beam may be irradiated onto the first amorphous layer 15 so as to cause the first amorphous layer 15 to undergo a phase change resulting in the second seed layer 16. A melt zone may extend to the first seed layer 14′, and the single crystalline structure of the first seed layer 14′ may influence the phase change of the first amorphous layer 15, so as to convert the first amorphous layer 15 into the second seed layer 16 having a single crystalline structure.

The first amorphous layer 15 may be irradiated with the first laser beam so as to heat the first amorphous layer 15 to a predetermined temperature. Where the first amorphous layer 15 includes silicon, the first laser beam may be heated to a temperature of greater than or equal to about 1,410° C. for an amorphous silicon layer having a melting point of about 1,410° C. Where the first amorphous layer 15 includes germanium, the first amorphous layer 15 may be heated to a temperature of greater than or equal to about 937° C. for an amorphous germanium layer having a melting point of about 937° C. Of course, the predetermined temperature may be varied depending on the material of the first amorphous layer 15.

Referring to FIG. 2E, a second amorphous layer 18 may be formed on the second seed layer 16 (operation 350). The second amorphous layer 18 may also be formed on the insulation layer pattern 12, e.g., adjacent to the opening 13. The second amorphous layer 18 may be formed by, e.g., a chemical vapor deposition (CVD) process. While the thickness of the second amorphous layer 18 is not restricted to a particular thickness, it may be advantageous if the second amorphous layer 18 is relatively thin.

Where the first seed layer 14, 14′ and the second seed layer 16 are single crystalline silicon, the second amorphous layer 18 may be an amorphous silicon layer. Where the first seed layer 14, 14′ and the second seed layer 16 are single crystalline germanium, the second amorphous layer 18 may be an amorphous germanium layer.

Referring to FIGS. 2F and 2G, the second amorphous layer 18 may be crystallized to yield a single crystalline layer 20 (operation 360). In an implementation, a second laser beam may be irradiated onto the second amorphous layer 18. When forming the single crystalline layer 20, the second seed layer 16 should influence the crystallization of the amorphous layer 18. Therefore, in an implementation, the second laser beam may be irradiated onto the second amorphous layer 18 so that a melt zone in the second amorphous layer 18 extends to the interface of the second amorphous layer 18 with the second seed layer 16.

In an implementation, a laser emitter for emitting the first laser beam may be substantially the same as that for emitting the second laser beam. Accordingly, process efficiency may be enhanced in comparison to the case in which the laser emitter for emitting the first laser beam is different from that for emitting the second laser beam.

The amorphous layer 18 may be heated to a melting temperature. In an implementation, the second laser beam may be irradiated onto the second amorphous layer 18 so as to heat the second amorphous layer 18 to its melting temperature. For example, where the second amorphous layer 18 includes silicon, the second laser beam may used to heat the amorphous silicon layer to a temperature of greater than or equal to about 1,410° C. Where the second amorphous layer 18 includes germanium, the second laser beam may be used to heat the amorphous germanium layer to a temperature of greater than or equal to about 937° C.

When the second laser beam is irradiated onto the second amorphous layer 18, a phase change may be generated in the second amorphous layer 18, i.e., the second laser beam may change the phase of the second amorphous layer 18 to a liquid phase. As phase change may take only about several nanoseconds, the liquefied second amorphous layer 18 may not flow from the insulation layer pattern 12 having the second seed layer 16. That is, after the second amorphous layer 18 is changed into the liquefied phase within about several nanoseconds, the liquefied second amorphous layer 18 may be returned to a solid.

Larger grains may be obtained by reducing a temperature gradient. Accordingly, in an implementation, the second amorphous layer 18 may be separately heated at the same time it is being irradiated with the second laser beam, which may reduce a temperature gradient in the second amorphous layer 18 during the phase change.

As described above, the second laser beam may be irradiated onto the second amorphous layer 18, with the second single crystalline structure of the second seed layer 16 influencing the crystallization of the second amorphous layer 18 so as to change the second amorphous layer 18 into the single crystalline layer 20 through a phase change. Thus, during the phase change generated by heating with the second laser beam, the second seed layer 16, which may have a single crystalline structure, may function as a seed. That is, for example, where the second amorphous layer 18 includes silicon, the second amorphous silicon layer 18 may be changed into a single crystalline silicon layer by heating it with the second laser beam.

As described above, according to an embodiment of the present invention, the upper portion of the first seed layer 14 may be treated, e.g., using an ion implantation process, to convert the upper portion of the first seed layer 14 into the first amorphous layer 15, thereby removing the facet morphology from the upper portion the first seed layer 14 having the first single crystalline structure.

Conventional methods may yield subsequently-formed layers that are affected by the facet morphology of the seed layer. For example, where a single crystalline layer is obtained by crystallizing an amorphous layer that is formed directly on the first seed layer, the facet morphology of the first seed layer may be directly translated into the single crystalline layer. As a result of the facet morphology being translated into the single crystalline layer, a device fabricated using the single crystalline layer may exhibit poor electrical reliability.

According to embodiments of the present invention, during crystallization of the second seed layer 16, a facet morphology of the underlying first seed layer 14 may be propagated into the second seed layer 16. If the facet morphology were to propagate to the uppermost surface of the second seed layer 16, it could be further propagated into the single crystalline layer 20 that is subsequently formed on the second seed layer 16.

That is, referring to FIGS. 2E-2G, in order to form the single crystalline layer 20 on the substrate 10, the amorphous layer 18 may be formed on the surface 16a of the second seed layer 16 and on a surface 12a of the insulating layer 12. The amorphous layer 18 may then be crystallized to form the single crystalline layer 20, where a seed layer formed in the opening 13 seeds the crystal structure of the single crystalline layer 20. As discussed above, it will be appreciated that a facet morphology in the seed layer could be translated into the single crystalline layer 20, unless the facet morphology is eliminated from the seed layer. Thus, as described above, in an embodiment of the present invention, a portion of the first seed layer 14 may be converted into the amorphous layer 15.

Upon recrystallization of the amorphous layer 15, however, the facet morphology of the underlying seed layer 14 may again be imparted to the recrystallized seed layer, i.e., to the second seed layer 16. However, if the facet morphology of the recrystallized seed layer is substantially prevented from extending to a surface 16a of the second seed layer 16, then the facet morphology may be prevented from influencing the crystal structure that develops as the amorphous layer 18 crystallizes into the single crystalline layer 20.

According to this embodiment of the present invention, even if a facet morphology is propagated into the second seed layer 16 from the underlying first seed layer 14, the facet morphology may not be propagated to the surface 16a of the second seed layer 16. Thus, the facet morphology may not be translated into the single crystalline layer 20 obtained from the second amorphous layer 18 that is formed on the surface 16a.

A device fabricated using a single crystalline layer as formed above may include two or more crystal structures in the opening 13. That is, the lower portion of the opening 13 may include the first seed layer 14, which may exhibit a facet morphology, while the upper portion of the opening 13 may include the second seed layer 16, which may not exhibit the facet morphology.

After completing the above-described processes illustrated with reference to FIGS. 2A to 2D, the facet morphology may not be formed in the single crystalline layer 20. In particular, according to an embodiment of the present invention, a predetermined portion of the first seed layer 14 may be converted into the first amorphous layer 15, which may be subsequently recrystallized into the second seed layer 16 without the facet morphology extending to an upper surface 16a of the second seed layer 16. In an implementation, referring to FIG. 2C, the thickness -t- of an upper portion of the first seed layer 14 may be converted into the first amorphous layer 15.

That is, the first amorphous layer 15 may have a thickness -t-, where the thickness -t- corresponds to a depth measured from an upper face 14a of the first seed layer 14. The thickness -t- of the amorphous layer may reduce or eliminate the undesirable effects of a facet morphology that may redevelop when the first amorphous layer 15 is recrystallized.

According to an embodiment of the present invention, the thickness -t- may be determined, at least in part, based on a width -w- of the opening 13. For example, the thickness -t- may be determined based on the width of the first seed layer 14 in the opening 13. In an implementation, the thickness -t- may be determined, at least in part, based on a sidewall profile of the opening 13.

In detail, the single crystalline structure of the first seed layer 14 may exhibit a facet morphology having a particular angle with reference to the underlying single crystalline substrate 10. That is, the single crystalline structure of the first seed layer 14 may not be oriented substantially in parallel with the surface of the single crystal substrate 10. Rather, the single crystalline structure of the first seed layer 14 may be inclined with respect to the crystal plane of the substrate 10. For example, if the single crystalline structure of the first seed layer 14 has a {111} crystal plane, the first single crystalline structure of the first seed layer 14 may have a facet morphology that is inclined by about 54.7° with respect to the substrate 10.

The thickness -t- may be determined such that any facet morphology that develops in the second seed layer 16 terminates before reaching the surface 16a of the second seed layer 16, e.g., by terminating in a sidewall of the opening 13. In particular, since a facet morphology would develop at an angle and would start at the surface 14a of the first seed layer 14, the thickness -t- may be set so that the aspect ratio of the second seed layer results in crystal facets encountering the sidewall of the opening 13, rather than the surface 16a of the second seed layer 16. For example, where a sidewall profile of the opening 13 is straight, i.e., having sidewalls normal to the substrate 10, the thickness -t- may be set such that the ratio of the thickness -t- to the width -w- may be approximately equal to the tangent of the angle formed by the facet morphology. In an implementation, the angle may be 54.7°, the tangent of, the angle may be about 1.4, and the thickness -t- may be about 1.4 times the width -w-.

For example, if the width -w- is about 70 nm, the thickness -t- may be about 100 nm, if the width -w- is about 90 nm, the thickness -t- may be about 125 nm, and if the width -w- about 100 nm, the thickness -t- may be about 140 nm, etc. In another implementation, the thickness -t- may be about 1.3 times to about 1.5 times the width -w- of the opening 13.

As described above, in an embodiment of the present invention, a single crystalline layer 20 may be obtained by a phase change, without being influenced by a facet morphology. Thus, the facet morphology may not develop in the single crystalline layer 20. As a result, when the single crystalline layer 20 is used as a channel layer, the channel layer may provide improved electrical reliability.

Further, where the phase change is induced using a laser beam, the single crystalline layer 20 may have a dense crystal structure, and large grains may be readily obtained.

Furthermore, a single crystalline layer 20 formed according to embodiments of the present invention may be advantageously used as an active region of a stack type semiconductor device. Therefore, a gate pattern, a metal wiring, a logic device, etc., may be formed on the single crystalline layer 20.

According to embodiments of the present invention, a facet morphology may be reduced or eliminated from a single crystalline layer that is used for the channel layer in a stack structure. Thus, the single crystalline layer may have improved electrical reliability. In particular, embodiments of the present invention may be employed in manufacturing a highly-integrated semiconductor device having the stack structure.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming a layer, comprising:
forming an insulation layer having an opening on a single crystalline substrate, the opening partially exposing an upper face of the substrate;
forming a first seed layer in the opening;
converting an upper portion of the first seed layer into a first amorphous layer;
converting the first amorphous layer into a second seed layer;
forming a second amorphous layer on the second seed layer; and
converting the second amorphous layer into a single crystalline layer.

2. The method as claimed in claim 1, wherein the substrate is at least one of single crystalline silicon and single crystalline germanium.

3. The method as claimed in claim 1, wherein the insulation layer comprises oxide.

4. The method as claimed in claim 1, wherein converting the first seed layer into the first amorphous layer comprises implanting the first seed layer with ions.

5. The method as claimed in claim 4, wherein the substrate is at least one of single crystalline silicon and single crystalline germanium, and
the ions include at least one of silicon, germanium, arsenic, phosphorous and boron.

6. The method as claimed in claim 1, wherein a thickness of the first amorphous layer is about 1.3 times to about 1.5 times a width of the opening.

7. The method as claimed in claim 1, wherein a thickness of the first amorphous layer is determined based on an angle of intersection between a crystal plane of the substrate and a crystal plane of the first seed layer.

8. The method as claimed in claim 7, wherein the thickness of the first amorphous layer is also determined based on a sidewall profile of the opening.

9. The method as claimed in claim 1, wherein a thickness of the first amorphous layer corresponds to:
a width of the first seed layer in the opening; and
an angle of intersection between a crystal plane of the substrate and a crystal plane of the first seed layer.

10. The method as claimed in claim 9, wherein the thickness of the first amorphous layer is approximately equal to the tangent of the angle times the width of the first seed layer.

11. The method as claimed in claim 10, wherein the substrate has a {100} crystal structure, the first seed layer has a {111} crystal structure, the angle of intersection between the substrate and the first seed layer is approximately 54.7°, and the thickness of the first amorphous layer is approximately equal to 1.4 times the width of the first seed layer.

12. The method as claimed in claim 1, wherein the first seed layer is formed using epitaxy.

13. The method as claimed in claim 12, wherein the first seed layer has a same composition as the single crystalline substrate.

14. The method as claimed in claim 1, wherein the first seed layer has a facet morphology, and converting the upper portion of the first seed layer into the first amorphous layer removes the facet morphology from the upper portion of the first seed layer.

15. The method as claimed in claim 1, wherein the first amorphous layer is converted into the second seed layer by heating the first amorphous layer with a laser.

16. The method as claimed in claim 15, wherein the second amorphous layer is converted into the single crystalline layer by heating the second amorphous layer with a laser.

17. The method as claimed in claim 16, wherein a laser emitter for converting the first amorphous layer is substantially the same as that for converting the second amorphous layer.

18. The method as claimed in claim 16, wherein converting the first amorphous layer includes heating the first amorphous layer to its melting temperature, and
converting the second amorphous layer includes heating the second amorphous layer to its melting temperature.

19. The method as claimed in claim 1, wherein the substrate has a {100} crystal structure and the first seed layer has a {111} crystal structure.

20. The method as claimed in claim 1, wherein a thickness of the first amorphous layer corresponds to a crystal structure of the first seed layer.
